(19) United States
(12) Patent Application Publication
(10) Pub. No.: US 2020/0328732 A1
(43) Pub. Date: Oct. 15, 2020

(54) SEMICONDUCTOR DEVICE

(71) Applicant: RENESAS ELECTRONICS CORPORATION, Tokyo (JP)

(72) Inventors: Takashi TASAKI, Tokyo (JP); Shunya NAGATA, Tokyo (JP)

(21) Appl. No.: 16/828,582

(22) Filed: Mar. 24, 2020

(30) Foreign Application Priority Data
Apr. 12, 2019 (JP) 2019-076378

(51) Int. Cl. H03K 3/037; H03K 19/20; H03K 5/14

(52) U.S. Cl. CPC H03K 3/037; H03K 5/14; H03K 19/20

(57) ABSTRACT

A semiconductor device includes: a plurality of P-channel type MOS transistors each whose source-drain path being coupled between a first wiring to which a power supply potential is to be supplied and a power supply node included in a logic circuit block, and a plurality of N-channel type MOS transistors each whose source-drain path being coupled between a ground node included in the logic circuit block and a second wiring to which a ground potential is to be supplied. Also, during standby state, each of the plurality of P-channel type MOS transistors and the plurality of N-channel type MOS transistors is diode-connected. According to the above semiconductor device, the current consumption of a logic circuit included in the logic circuit block during standby state can be reduced, and the logic circuit can be returned from standby state to normal operation state in a short time.

### CROSS-REFERENCE TO RELATED APPLICATIONS

The disclosure of Japanese Patent Application No. 2019-076378 filed on Apr. 12, 2019 including the specification, drawings and abstract is incorporated herein by reference in its entirety.

### BACKGROUND

The present disclosure relates to a semiconductor device, and more particularly, the present disclosure is applicable to a semiconductor device including a logic circuit portion.

A semiconductor device such as a microcontroller (hereinafter also called “MCU”) is comprised of a central processing unit (CPU), a storage device, a peripheral circuit comprising a peripheral function, and the like. The central processing unit can be regarded as a logic circuit portion comprised of a plurality of logic circuits.

In order to make a low current consumption during standby state, in the logic circuit portion of the semiconductor device, a power supply cut-off technique that cuts off the power supply of the logic circuit portion has been proposed (for example, Patent Document 1 and Patent Document 2). Patent Document 1 also discloses a power supply control technique for SRAM modules.

Also, there is another method for making a low current consumption during standby state, in the logic circuit portion of the semiconductor device, that lowers the power supply potential supplied to the logic circuit portion by reducing the output voltage of the regulator included in the power supply circuit, thereby reducing the leakage current of the plurality of transistors included in the logic circuit portion.

There are disclosed techniques listed below.

[Patent Document 1] Japanese Unexamined Patent Application Publication No. 2011-60401

[Patent Document 2] Japanese Unexamined Patent Application Publication No. 2014-99165

### SUMMARY

The power supply cut-off technique has a high effect of lowering the current consumption of the logic circuit portion during standby. When a low-current MCU is used, the MCU is mainly operated intermittently such that the normal operation state (normal operation mode, “MAINRUN”) and the standby state (standby mode, “Standby”) are repeated. The recovery from the standby state to the normal operation state requires a high-speed recovery. When the power supply cut-off is performed, a complicated start-up sequence is required. Accordingly, the recovery time and the current consumption may be increased. Further, since the power supply is not supplied to the logic circuit portion whose power supply cut-off was performed, it is also impossible to retain the information at the standby time.

Reducing the output voltage of the regulator is effective in reducing the power supply consumption of the entire logic circuit portion. However, depending on the electric characteristics of the transistor, the logic circuit portion itself may not operate in some cases. In this case, it is necessary to adjust the voltage such as a technique that the output voltage of the regulator is lowered in accordance with the minimum operating voltage of the logic circuit portion.

It is an object of the present disclosure to provide a technique capable of reducing the current consumption of a logic circuit during standby state, and recovering from the standby state to the normal operation state in a short time.

Other objects and novel features will become apparent from the description of this specification and the accompanying drawings.

An outline of a typical one of the present disclosure will be briefly described as follows.

According to an embodiment, a semiconductor device comprises: a first wiring to which a power supply potential is to be supplied; a second wiring to which a ground potential is to be supplied; a logic circuit block including a power supply node, a ground node, and a plurality of logic circuits; a first switch circuit provided between the first wiring and the power supply node; and a second switch circuit provided between the ground node and the second wiring. The first switch circuit includes a plurality of P-channel type MOS transistors, a source-drain path of each of the plurality of P-channel type MOS transistors being coupled between the first wiring and the power supply node. The second switch circuit includes a plurality of N-channel type MOS transistors, a source-drain path of each of the plurality of N-channel type MOS transistors being coupled between the ground node and the second wiring. During standby state, the plurality of P-channel type MOS transistors is diode-connected. And, during standby state, the plurality of N-channel type MOS transistors is diode-connected.

According to the above semiconductor device, the current consumption of the logic circuit during standby state can be reduced, and the logic circuit can be returned from the standby state to the normal operation state in a short time.

### BRIEF DESCRIPTION OF THE DRAWINGS

FIG. 1 is a diagram showing a configuration example of the semiconductor device according to an embodiment.

FIG. 2 is a diagram for explaining a configuration example of the logic circuit portion according to the embodiment.

FIG. 3 is a diagram showing a configuration example of the buffer circuit BUF1 shown in FIG. 2.

FIG. 4 is a diagram showing a configuration example of the buffer circuit BUF2 shown in FIG. 2.

FIG. 5 is a diagram showing a configuration example of the semiconductor device according to a first modified example.

FIG. 6 is a diagram showing a configuration example of the semiconductor device according to a second modified example.

FIG. 7 is a diagram for explaining a configuration example of the logic circuit portion according to the second modified example.

FIG. 8 is a diagram showing a configuration example of the semiconductor device according to a third modified example.

FIG. 9 is a diagram for explaining a configuration example of the logic circuit portion according to the third modified example.

FIG. 10 is a diagram for explaining a configuration example of the logic circuit portion according to a fourth modified example.

FIG. 11 is a diagram for explaining a configuration example of the logic circuit portion according to a fifth modified example.

FIG. 12 is a diagram for explaining a configuration example of the logic circuit portion according to a sixth modified example.

FIG. 13 is a block diagram showing a configuration example of the semiconductor device according to an application example.

FIG. 14 is a diagram showing a configuration example of a regulator included in a power supply circuit.

### DETAILED DESCRIPTION

An embodiment will be described below with reference to the drawings. However, in the following description, the same components are denoted by the same reference numerals, and a repetitive description thereof may be omitted. It should be noted that the drawings may be represented schematically in comparison with actual embodiments for the sake of clarity of explanation, but are merely an example and do not limit the interpretation of the present invention.

### Embodiment

### Configuration Example

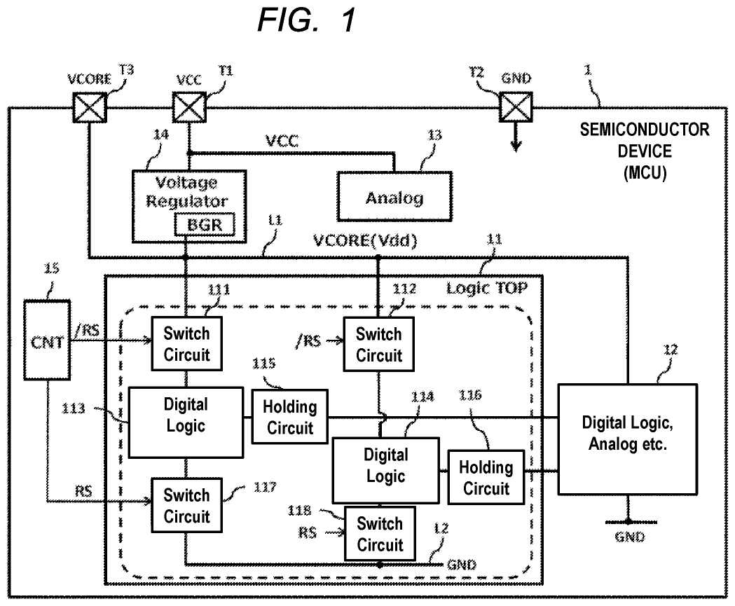

FIG. 1 is a diagram showing a configuration example of the semiconductor device according to an embodiment.

The semiconductor device 1 is formed on one semiconductor chip such as a monocrystalline silicon chip by using a manufacturing method of a known CMOS transistor. The semiconductor device 1 is, in one instance, a microcontroller, hereinafter also referred to as a micro-controller. The semiconductor device 1 includes an external terminal T1 to which a power supply potential VCC serving as a first ground potential is supplied, an external terminal T2 to which a grounding potential GND serving as a second ground potential smaller than the first ground potential is supplied, and an external terminal T3 to which a core voltage VCORE is supplied. The core voltage VCORE has a potential between the power supply voltage VCC and the ground potential GND.

The semiconductor device 1 further includes a logic circuit portion 11, a circuit portion 12, an analogue circuit 13, a power supply circuit 14, and a control circuit 15. Logic circuitry 11 may be viewed as a central device of MCUs in one instance. The circuit portion 12 includes a digital logic circuit such as a timer circuit, an analog circuit such as a digital-to-analog conversion circuit, and the like, and is connected to the logic circuit portion 11 so as to receive an output from the logic circuit portion 11. The analog circuit 13 receives the power supply potential VCC supplied to the first external terminal T1, and may be, for example, an analog-to-digital conversion circuit ADC. The circuit portion 12 and the analog circuit 13 can be regarded as peripheral circuits constituting peripheral functions of the MCU.

The power supply circuit 14 includes a regulator that steps down the power supply potential VCC supplied to the first external terminal T1 based on the reference potential generated by the band gap reference circuit BGR to generate a core voltage VCORE (Vdd) (hereinafter, the core voltage VCORE (Vdd) may be referred to as Vdd). The core voltage VCORE Vdd generated by the power supply circuit 14 is supplied to the logic circuit portion 11 and the circuit portion 12. The core voltage VCORE Vdd may use the core voltage VCORE supplied to the third external terminal T3.

The control circuit (CNT) 15 generates a standby signal (RS) and a standby signal (RS), and controls a normal operation state and a standby state of the logic circuit portion 11. The standby signal/RS generated by the control circuit CNT 15 is set to a first state such as a high level in a normal operation state, and is set to a second state such as a low level, during a standby state. The standby signal RS is set to a second condition such as a low level in a normal operation state, and is set to a first state such as a high level during a standby state. The standby signal/RS is an inverted standby signal, and the standby signal RS may be referred to as a non-inverted standby signal.

In this embodiment, the logic circuit portion 11 includes two switch circuits 111 and 112 provided on the core-voltage VCORE (Vdd) side, two logic circuit blocks (Digital Logic) 113 and 114, two holding circuits 115 and 116, and two switch circuits 117 and 118 provided on the ground potential GND side. The logic circuit block 113 is connected to the power supply wiring (first wiring) L1 to which the core voltage VCORE (Vdd) is supplied via the switch circuit (first switch circuit) 111, and is connected to the ground wiring (second wiring) L2 to which the ground potential GND is supplied via the switch circuit (second switch circuit) 117. The output of the logic circuit block 113 is supplied to the circuit portion 12 via the holding circuit 115. The logic circuit block 114 is connected to the power supply line L1 to which the core voltage VCORE (Vdd) is supplied via the switch circuit (first switch circuit) 112, and the logic circuit block 114 is connected to the ground line L2 to which the ground voltage GND is supplied via the switch circuit (second switch circuit) 118. The output of the logic circuit block 114 is supplied to the circuit portion 12 via the holding circuit 115.

Each of the switch circuits 111 and 112 includes a plurality of P-channel type MOS transistors controlled based on the standby signal/RS. The standby signal/RS is supplied to the gate electrodes of a plurality of P-channel type MOS transistors. The source-drain paths of the plurality of P-channel type MOS transistors are connected in parallel with each other. The source-drain paths of the plurality of P-channel type MOS transistors are coupled such that the core voltage VCORE Vdd is supplied to the logic circuit blocks 113 and 114 based on the high level of the standby signal/RS during the normal operation state. On the other hand, during the standby state, the plurality of P-channel type MOS transistors are diode-connected based on the low level of the standby signal/RS, and supply the first potential LGVdd (LGVdd=Vdd-Vtp, which is lowered from the core voltage VCORE (Vdd) by the threshold voltage (Vtp) of the diode, to the logic circuit blocks 113 and 114.

Each of the switch circuits 117 and 118 includes a plurality of N-channel type MOS transistors controlled based on the standby signal RS. The standby signal RS is supplied to the gate electrodes of a plurality of N-channel type MOS transistors. The source-drain paths of the plurality of N-channel type MOS transistors are connected in parallel with each other. The source-drain paths of plurality of N-channel type MOS transistors are coupled so as to supply the ground potential GND to the logic circuit blocks 113 and 114 based on the low level of the standby signal RS during a normal operation state. On the other hand, during the standby state, the plurality of N-channel type MOS transistors are diode-connected based on the high level of the standby signal RS, and supply the logic circuit block 113 and the logic circuit block 114 with the second potential LGVss (LGVss=Vss+Vtn which is increased by the threshold voltage (Vtn) of the diode from the ground potential GND (hereinafter, also referred to as Vss). It is assumed that the potential difference between the first potential LGVdd and the second potential LGVdd is such that, during the standby state, the internal logic circuits constituting the logic circuit blocks 113 and 114 have such a potential difference that the internal logic circuits can hold the signal state in the normal operation state.

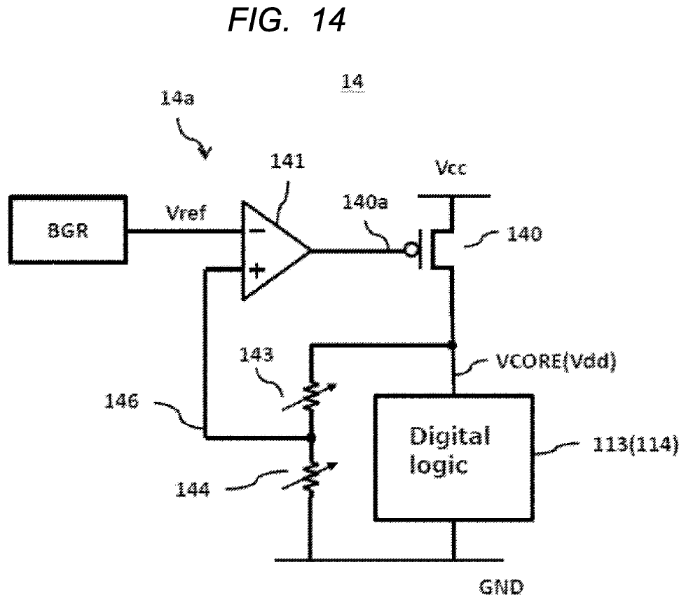

FIG. 14 is a diagram showing a configuration example of the regulator 14a included in the power supply circuit 14. The regulator 14a includes a P-channel type MOS transistor 140 that generates a core voltage VCORE (Vdd) as a step-down voltage from a power supply potential VCC, and an amplifier 141 that controls a gate voltage of the P-channel type MOS transistor 140. The regulator 14a further includes variable resistive elements 143 and 144 for dividing the core voltage VCORE (Vdd), and a band gap reference circuit (BGR) 145 for generating a reference voltage Vref. In the regulator 14a, the amplifier circuit 141 is connected to a reference voltage Vref and a voltage 146 obtained by voltage division by the variable resistive elements 143 and 144, and the gate voltage 140a of the P-channel type MOS transistor 140 is controlled so that the reference voltage Vref and the gate voltage 146 are equal to each other to obtain a desired core voltage VCORE Vdd.

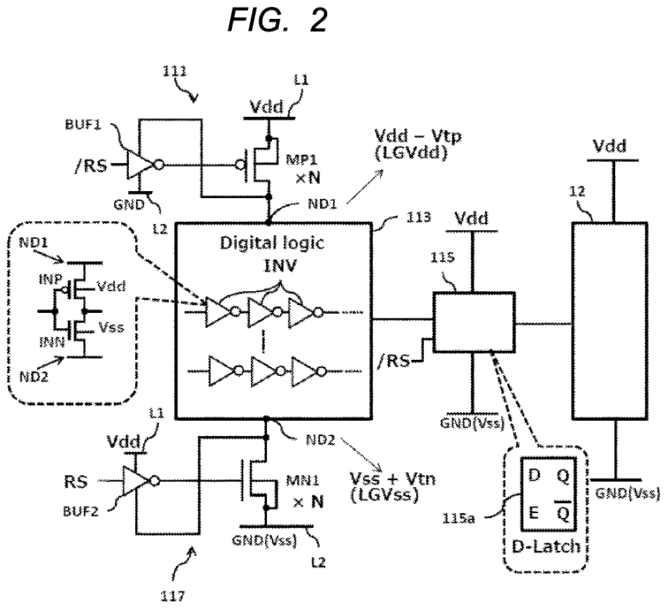

The following descriptions 1) to 3) are for the case where the switch circuits 111, 117, 112, and 118 are not provided in FIGS. 1 and 2.

1) The leakage current of the logic circuit portion 11 can be reduced by reducing the core voltage VCORE Vdd, which is the output voltage of the regulator 14a. When the logic circuit blocks 113 and 114 are the logic circuit blocks that need to be operated at high speed during the normal operation state, the core voltage VCORE Vdd, which is the output power of the regulator 14a, is 1. 5V, for example, during the normal operation state. When the logic circuit block 113 or the logic circuit block 114 shifts to the standby state, the output power of the regulator 14a is reduced from 1. 5V to 1. 3V, for example. This makes it possible to reduce the leakage current of the logic circuit blocks 113 and 114 during the standby state.

2) In addition, when the logic circuit blocks 113 and 114 are the logic circuit blocks that do not require the speed during the normal operation state but desire to operate with the current consumption reduced as much as possible, the output power of the regulator 14a is reduced from 1. 5V to 1. 1V during the normal operation state, for example. As a result, the current consumption of the logic circuit blocks 113 and 114 can be reduced.

3) Reducing the core voltage VCORE Vdd, which is the output voltage of the regulator 14a, is effective in reducing the power consumption of the entire logic circuit portion 11. However, depending on the electric characteristics of the transistor, the logic circuit portion 11 itself may not operate in some cases. In this case, it may be necessary to adjust the voltage such that the output voltage of the regulator is lowered in accordance with the minimum operating voltage of the logic circuit portion 11.

### Configuration Example

Next, a specific configuration example will be described using the logic circuit block 113, the switch circuits 111 and 117, and the holding circuit 115 as a representative example. The configuration of the logic circuit block 114, the switch circuits 112 and 118, and the holding circuit 116 can be the same as the configuration of the logic circuit block 113, the switch circuits 111 and 117, and the holding circuit 115.

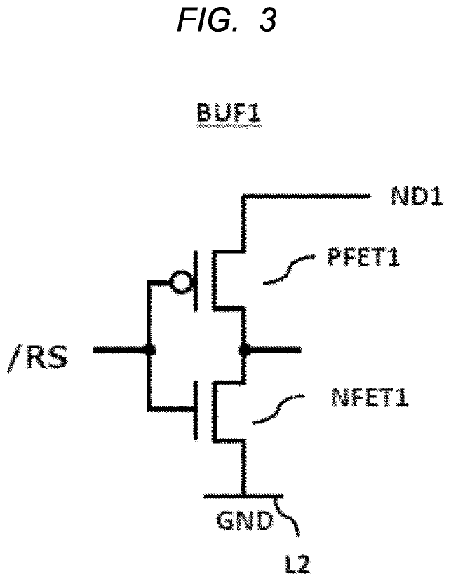

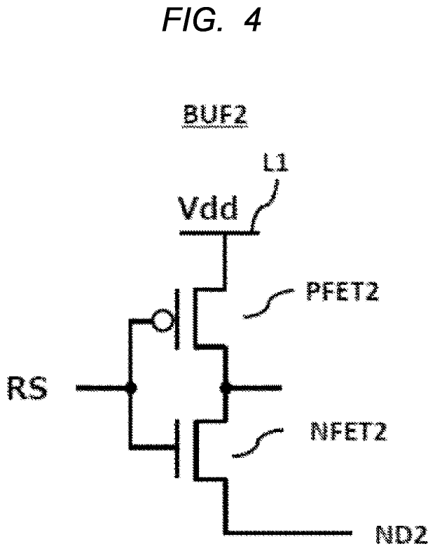

FIG. 2 is a diagram for explaining a configuration example of the logic circuit portion according to the embodiment. FIG. 2 shows a configuration example of the logic circuit block 113, the two switch circuits 111 and 117, and the holding circuit 115 in FIG. 1. FIG. 3 is a diagram showing a configuration example of the buffer circuit BUF1 shown in FIG. 2. FIG. 4 is a diagram showing a configuration example of the buffer circuit BUF2 shown in FIG. 2.

The switching circuit 111 includes a buffer circuit BUF1 and a plurality of P-channel type MOS transistors MP1. The buffer circuitry BUF1 includes inputs and outputs for receiving the standby signal/RS. The plurality of P-channel type MOS transistors MP1 are N P-channel type MOS transistors MP1. Each of the gate electrodes of the plurality of P-channel type MOS transistors MP1 is connected to the outputs of the buffer circuits BUF1. Each of the source electrodes of the plurality of P-channel type MOS transistors MP1 is connected to the power supply line L1 to which the core voltage VCORE Vdd is supplied. Each of the drain electrodes of the plurality of P-channel type MOS transistors MP1 is connected to the power supply node ND1 of the logic circuit block 113. That is, the source-drain paths of the plurality of P-channel type MOS transistors are connected in parallel with each other between the power supply line L1 and the power supply node ND1.

As shown in FIG. 3, the buffer circuit BUF1 includes a P-channel type MOS transistor (first P-channel type MOS transistor) PFET1 and an N-channel type MOS transistor (first N-channel type MOS transistor) NFET1. The gates of the P-channel type MOS transistors PFET1 are connected to the inputs of the buffer circuits BUF1. The source of the P-channel type MOS transistor PFET1 is connected to the power supply node ND1 of the logic circuit block 113, that is, the drain electrodes of the plurality of P-channel type MOS transistors MP1. The drain of the P-channel type MOS transistor PFET1 is connected to the output of the buffer circuit BUF1. The gates of the N-channel type MOS transistors NFET1 are connected to the inputs of the buffer circuits BUF1. The source of the N-channel type MOS transistor NFET1 is connected to the ground line L2 to which the ground potential GND is supplied. The drains of the N-channel type MOS transistors NFET1 are connected to the outputs of the buffer circuits BUF1. That is, the source-drain path of the P-channel type MOS transistor PFET1 and the source-drain path of the N-channel type MOS transistor NFET1 are coupled in series between the power supply node ND1 and the ground line L2.

The switching circuit 111 and the buffer circuit BUF1 can be regarded as a voltage control circuit for controlling the potential of the power supply nodes ND1 of the logic circuit blocks 113.

The switching circuit 117 includes a buffer circuit BUF2 and a plurality of N-channel type MOS transistors MN1. The buffer circuit BUF2 includes inputs and outputs for receiving the standby signal RS. The plurality of N-channel type MOS transistors MN1 are N N-channel type MOS transistors MN1. Each of the gate electrodes of the plurality of N-channel type MOS transistors MN1 is connected to the outputs of the buffer circuits BUF2. Each of the source electrodes of the plurality of N-channel type MOS transistors MN1 is connected to the ground line L2 to which the ground potential GND is supplied. Each of the drain electrodes of the plurality of N-channel type MOS transistors MN1 is connected to the ground node ND2 of the logic circuit block 113. That is, the source-drain paths of the plurality of N-channel type MOS transistors are connected in parallel with each other between the ground line L2 and the ground node ND2.

As shown in FIG. 4, the buffer circuit BUF2 includes a P-channel type MOS transistor (second P-channel type MOS transistor) PFET2 and an N-channel type MOS transistor (second N-channel type MOS transistor) NFET2. The gates of the P-channel type MOS transistors PFET2 are connected to the inputs of the buffer circuits BUF2. The source of the P-channel type MOS transistor PFET2 is connected to the power supply line L1 to which the power supply potential Vdd is supplied. The drain of the P-channel type MOS transistor PFET2 is connected to the output of the buffer circuit BUF2. The gates of the N-channel type MOS transistors NFET2 are connected to the inputs of the buffer circuits BUF2. The sources of the N-channel type MOS transistors NFET2 are connected to the ground nodes ND2 of the logic-circuit blocks 113, that is, the drain electrodes of the plurality of N-channel type MOS transistors MN1. The drains of the N-channel type MOS transistors NFET2 are connected to the outputs of the buffer circuits BUF2. That is, the source-drain path of the P-channel type MOS transistor PFET2 and the source-drain path of the N-channel type MOS transistor NFET2 are coupled in series between the power supply line L1 and the grounding node ND2.

The switching circuit 117 and the buffer circuit BUF2 can be regarded as a voltage control circuit for controlling the potential of the grounding node ND2 of the logic circuit block 113.

The logic circuit block 113 includes a plurality of logic circuits, and the power supply terminal and the ground terminal of the plurality of logic circuits are connected to the power supply node ND1 and the ground node ND2, respectively. In this example, the logic circuit block 113 is represented to include a plurality of inverters INV. As shown in the enlarged view, the inverter INV includes a P-channel type MOS transistor INP and an N-channel type MOS transistor INN, and the source-drain path of the P-channel type MOS transistor INP and the source-drain path of the N-channel type MOS transistor INN are coupled in series between the power supply node ND1 and the ground node ND2. The gate electrode of the P-channel type MOS transistor INP and the gate electrode of the N-channel type MOS transistor INN are connected to each other and serve as an input terminal of the inverter INV. A common connection point between the source-drain path of the P-channel type MOS transistor INP and the source-drain path of the N-channel type MOS transistor INN is an output terminal of the inverter INV. The P-channel type MOS transistor INP is formed in an N-type well formed in a semiconductor chip. The substrate gates of the P-channel type MOS transistors INP are formed of the N-type well, and the N-type well is connected to the power supply potential Vdd. The N-channel type MOS transistor INN is formed in a P-type well formed in the semiconductor chip. The substrate gates of the N-channel type MOS transistors INN are formed of the P-type well, and the P-type well is connected to the grounding potential Vss. The internal configuration of the logic circuit block 113 is not limited to a plurality of inverters INV. In addition to the plurality of inverters INV, the logic circuit block 113 may include a plurality of AND circuits, a plurality of NAND circuits, a plurality of OR circuits, a plurality of NOR circuits, a plurality of flip-flop circuits, and the like.

The holding circuit 115 holds the output of the logic circuit block 113. The holding circuit 115 may be a D-latch circuit (D-Latch) 115a, for example. In the D latch circuit 115a, the standby signal/RS is input to the enable terminal E, the output of the logic circuit block 113 is connected to the data terminal D, and the input of the circuit portion 12 is connected to the output Q. In this example, one holding circuit 115 is illustrated as a representative, but the present invention is not limited thereto. When the logic circuit block 113 has a plurality of outputs and the circuit portion 12 has a plurality of inputs, the plurality of holding circuits 115 are provided so that the plurality of outputs of the logic circuit block 113 and the circuit portion 12 are provided with one holding circuit 115 between each of the plurality of inputs.

Next, the operation of the switch circuits 111 and 117 will be described.

### In Case of Standby State

When shifting from the normal operation state to the standby state, the standby signal/RS transitions from the high level to the low level, and the standby signal RS transitions from the low level to the high level.

The P-channel type MOS transistor PFET1 in the buffer circuit BUF1 is to be in the ON-state based on the low level of the standby signal/RS. The N-channel type MOS transistor NFET1 in the buffer circuit BUF1 is to be in the OFF-state based on the low level of the standby signal/RS. When the P-channel type MOS transistor PFET1 is in the ON-state, the drains and gates of the plurality of P-channel type MOS transistors MP1 have the same voltages. Therefore, the plurality of P-channel type MOS transistors MP1 is diode-connected. Therefore, the voltage of the drains of the plurality of P-channel type MOS transistors MP1, that is, the voltage of the power supply nodes ND1 of the logic-circuit blocks 113 becomes the first potential LGVdd (LGVdd=Vdd-Vtp which is reduced from the core voltage VCORE (Vdd) by the threshold voltage (Vtp) of the plurality of P-channel type MOS transistors MP1.

On the other hand, the P-channel type MOS transistor PFET2 in the buffer circuit BUF2 is to be in the OFF-state based on the high level of the standby signal RS. The N-channel type MOS transistor NFET2 in the buffer circuit BUF2 is to be in the ON-state based on the high level of the standby signal RS. When the N-channel type MOS transistor NFET2 is in the ON-state, the drains and gates of the plurality of N-channel type MOS transistors MN1 have the same voltages. Therefore, the plurality of N-channel type MOS transistors MN1 is diode-connected. Therefore, the voltages of the drains of the plurality of P-channel type MOS transistors MP1, that is, the voltages of the ground nodes ND2 of the logic-circuit blocks 113 become the second potential LGVss (LGVss, which is increased from the ground potential Vss by the threshold voltage (Vtn) of the diodes, Vss+Vtn.

Therefore, without changing the output voltage of the power supply circuit 14, the logic circuit block 113 is supplied with the potential difference between the first potential LGVdd and the second potential LGVdd. Therefore, the internal logic circuit constituting the logic circuit block 113 can hold the signal state in the normal operation state. Since the potential difference between the first potential LGVdd and the second potential LGVdd is smaller than the potential difference between the power supply potential Vdd and the grounding potential Vss, the leakage current of the plurality of transistors included in the logic circuit block 113 can be reduced. As a result, the current consumption of the logic circuit block 113 in the standby state can be reduced.

When transitioning from the standby state to the normal operation state, the standby signal/RS transitions from the low level to the high level, and the standby signal RS transitions from the high level to the low level.

The P-channel type MOS transistor PFET1 in the buffer circuit BUF1 is to be in the OFF-state based on the high level of the standby signal/RS. The N-channel type MOS transistor NFET1 in the buffer circuit BUF1 is to be in the ON-state based on the high level of the standby signal/RS. When the N-channel type MOS transistor NFET1 is in the ON-state, the plurality of P-channel type MOS transistors MP1 are also to be in the ON-state, thereby the voltage of the power supply node ND1 of the logic-circuit block 113 becomes the power supply potential Vdd.

On the other hand, the P-channel type MOS transistor PFET2 in the buffer circuit BUF2 is to be in the ON-state based on the low level of the standby signal RS. The N-channel type MOS transistor NFET2 in the buffer circuit BUF2 is to be in the OFF-state based on the low level of the standby signal RS. When the P-channel type MOS transistor PFET2 is in the ON-state, the plurality of N-channel type MOS transistors MN1 is also to be in the ON-state, thereby the voltage of the ground node ND2 of the logic-circuit block 113 becomes the ground potential Vss.

As described above, the logic circuit block 113 returns from the standby state to the normal operation state. Therefore, since the logic circuit block 113 returns to the normal operation state while maintaining the signal state held in the standby state, the signal processing in the normal operation can be performed from the held signal state. The return from the standby state to the normal operation state only changes the signal levels of the standby signals/RS and RS, does not require a complicated start-up sequence, and does not increase the return time and current consumption.

### Holding Circuit 115

If the standby state, the high level of the signal output from the logic circuit block 113 is the potential of the first potential LGVdd (LGVdd=Vdd−Vtp), the low level of the signal output from the logic circuit block 113 is the potential of the second potential LGVss (LGVss=Vss+Vtn). On the other hand, since the power supply potential Vdd and the ground potential Vss are supplied to the circuit portion 12 provided at the subsequent stage of the logic circuit block 113, if the high level and the low level of the signal output from the logic circuit block 113 are input to the circuit portion 12, an indefinite signal may propagate in the circuit portion 12 or a through current may occur in the circuit portion 12. In order to prevent this, a holding circuit 115 for holding an output signal of the logic circuit block 113 is provided between the logic circuit block 113 and the circuit portion 12. Since the power supply potential Vdd and the ground potential Vss are supplied to the holding circuit 115, the high level of the output of the holding circuit 115 is the power supply potential Vdd, and the low level of the output of the holding circuit 115 is the ground potential Vss. As a result, it is possible to suppress the propagation of an indefinite signal and the through current in the circuit portion 12.

According to the embodiment, one or more of the following effects can be obtained.

1) Current consumption during standby of the semiconductor device 1 can be reduced.

2) Without changing the output voltage of the power supply circuit 14, a potential difference between the first potential LGVdd and the second potential LGVdd is supplied to the logic circuit blocks 113 and 114 of the logic circuit portion 11 by the switching circuits 111, 112, 117, and 118 during the standby state. Since the potential difference between the first potential LGVdd and the second potential LGVdd is smaller than the potential difference between the power supply potential Vdd and the grounding potential Vss, it is possible to reduce the leakage current of the plurality of transistors constituting the logic circuit blocks 113 and 114. As a result, the current consumption of the logic circuit blocks 113 and 114 during the standby state can be reduced.

3) Since the output voltage of the power supply circuit 14 does not need to be changed, it is possible to realize the normal operation state (MAINRUN: high-speed operation and high current consumption state) at the same time.

4) The recovery time from the standby state (Standby) to the normal operation state (MAINRUN) can be restored in a short time. That is, only the control of the switch circuits 111, 112, 117, and 118 is performed, and the power supply voltage which can operate during the normal operation state can be supplied to the logic circuit blocks 113 and 114 in a short time without depending on the analog circuit characteristics. Since it does not take a long time such as the stabilization time wait of the output voltage of the power supply circuit 14, it is also suitable for intermittent operation such as to repeat the normal operation state (MAINRUN) and the standby state (Standby).

5) As an advantage of reducing the current consumption in the embodiment, the leakage current of the logic circuit portion 11 in the semiconductor device 1 can be reduced by about 70% as compared with the case where the switching circuits 111, 112, 117, and 118 are not provided in the logic circuit portion 11.

### Modified Example

Several modified examples are described below modified example.

### First Modified Example

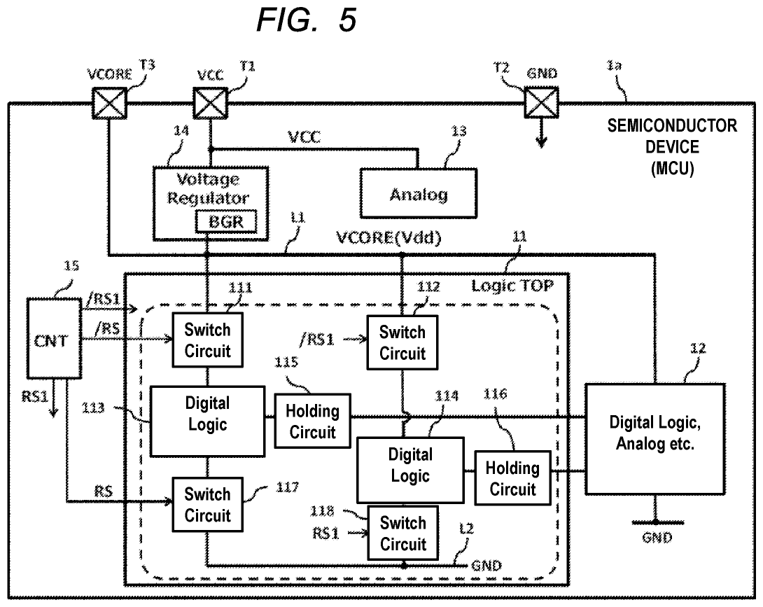

FIG. 5 is a diagram showing a configuration example of the semiconductor device 1a according to a first modified example. In the first modified example, components having the same functions as those in FIG. 1 of the embodiment are denoted by the same reference numerals, and descriptions thereof are omitted. In the semiconductor device 1 shown in FIG. 1, a configuration in which the standby signal/RS is supplied to the switch circuits 111 and 117 and the standby signal RS is supplied to the switch circuits 112 and 118 is shown, but the present invention is not limited thereto. In the semiconductor device 1a shown in FIG. 5, the control circuit 15a is modified to output the standby signals/RS and RS, and the standby signal RS1, RS1. The standby signal/RS is supplied to the switch circuit 111, and the standby signal RS is supplied to the switch circuit 112. On the other hand, the standby signal RS1 is supplied to the switch circuit 117, and the standby signal RS1 is supplied to the switch circuit 118. The controller 15a sets the signal levels of the standby signals/RS and RS to indicate the standby state, and sets the signal levels of the standby signal/RS1, RS1 to indicate the normal operation state. As a result, the logic circuit block 113 transitions to the standby state, and the logic circuit block 114 maintains the normal operation state. The controller 15 sets the signal levels of the standby signals/RS and RS to indicate the normal operation state, and sets the signal levels of the standby signal RS1, RS1 to indicate the standby state. As a result, the logic circuit block 113 maintains the normal operation state, and the logic circuit block 114 transitions to the standby state. Further, the controller 15a sets the signal levels of the standby signals/RS and RS and the signal levels of the standby signal/RS1, RS1 to indicate the standby status. As a result, the logic circuit blocks 113 and 114 transition to the standby state. Further, the controller 15a sets the signal levels of the standby signals/RS and RS and the signal levels of the standby signal/RS1, RS1 to indicate normal operation states. As a result, the logic circuit blocks 113 and 114 are set to the normal operation state.

According to the first modified example, the transition of the logic circuit block 113 to the standby state and the transition of the logic circuit block 114 to the standby state can be performed simultaneously or individually. As a result, the entire logic circuit blocks 113 and 114 can be placed in the standby state, or either one of the logic circuit blocks 113 and 114 can be placed in the standby state. In other words, an area for reducing the current consumption during standby can be freely selected within the semiconductor device 1a.

### Second Modified Example

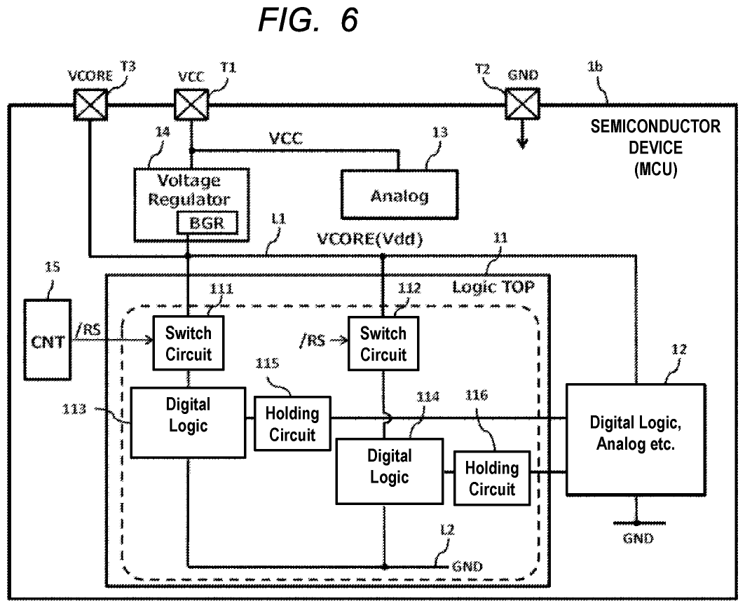

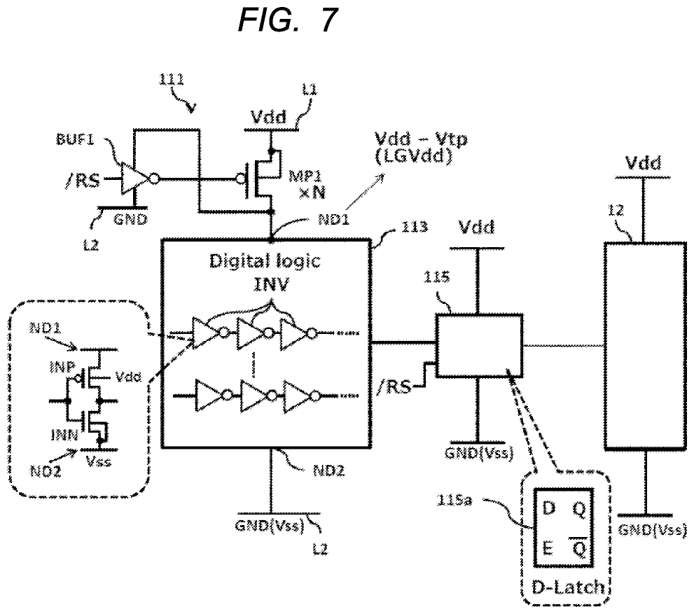

In the second modified example, components having the same functions as those in FIGS. 1 and 2 of the embodiment are denoted by the same reference numerals, and descriptions thereof are omitted. FIG. 6 is a diagram showing a configuration example of the semiconductor device 1b according to a second modified example. FIG. 7 is a diagram for explaining a configuration example of the logic circuit portion according to the second modified example. FIG. 6 differs from FIG. 1 in that the switching circuits 117 and 118 are not provided in the semiconductor device 1b shown in FIG. 6. FIG. 7 differs from FIG. in that the switch circuit 117 is not provided in FIG. 7. Therefore, the ground nodes ND2 of the logic-circuit blocks 113 are connected to the ground line L2.

Therefore, in the standby state, the power supply node ND1 of the logic circuit block 113 is set to the first potential LGVdd (LGVdd=Vdd−Vtp), and the ground node ND2 of the logic circuit block 113 is set to the ground potential Vss. In the inverters INV in the logic-circuit blocks 113, as shown in an enlarged view, the substrate gates of the P-channel type MOS transistors INP are formed of N-type well, and the N-type well is connected to the power supply potential Vdd. The substrate gates of the N-channel type MOS transistors INN are formed of P-type well, and the P-type well is connected to the grounding potential Vss.

### Third Modified Example

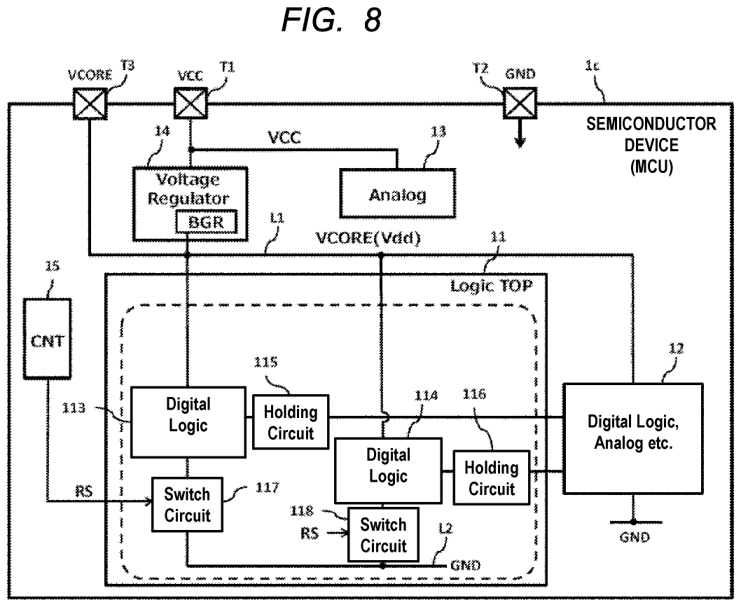

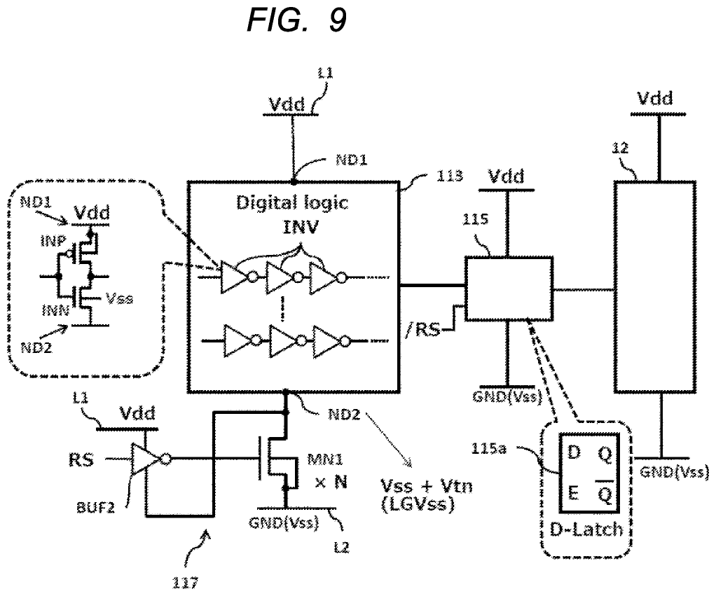

In the third modified example, components having the same functions as those in FIGS. 1 and 2 of the embodiment are denoted by the same reference numerals, and descriptions thereof are omitted. FIG. 8 is a diagram showing a configuration example of the semiconductor device 1c according to a third modified example. FIG. 9 is a diagram for explaining a configuration example of the logic circuit portion according to the third modified example. FIG. 8 differs from FIG. 1 in that the switching circuits 111 and 112 are not provided in the semiconductor device 1c of FIG. 8. FIG. 9 differs from FIG. 2 in that the switch circuit 111 is not provided in FIG. 9. Therefore, the power supply nodes ND1 of the logic-circuit blocks 113 are connected to the power supply lines L1.

Therefore, in the standby state, the power supply node ND1 of the logic circuit block 113 is set to the power supply potential Vdd, and the grounding node ND2 of the logic circuit block 113 is set to the second potential LGVss (LGVss=Vss+Vtn. In the inverters INV in the logic-circuit blocks 113, as shown in an enlarged view, the substrate gates of the P-channel type MOS transistors INP are formed of N-type well, and the N-type well is connected to the power supply potential Vdd. The substrate gates of the N-channel type MOS transistors INN are formed of P-type well, and the P-type well is connected to the grounding potential Vss.

In the structure of FIG. 2 according to the embodiment, it may be difficult to secure a potential difference between the first potential LGVdd (LGVdd=Vdd-Vtp of the power supply node ND1 and the second potential LGVss (LGVss of the grounding node ND2=Vss+Vtn due to electric characteristics of the transistor MP1,MN1. In the case of second modified example, 3, the potential difference between the power supply node ND1 and the grounding node ND2 is widened by Vtp or Vtn as compared with the case of the configuration of FIG. 2 of the embodiment, so that a sufficient potential difference can be ensured even if the electric characteristics of the transistor MP1 or MN1 are somewhat deteriorated. Further, in FIG. 7 of the second modified example and FIG. 9 of the third modified example, since only one of the two switching circuits 111 and 117 is used, the increase in the circuit area on the semiconductor chip can be reduced as compared with the increase in the circuit area on the semiconductor chip in FIG. 2.

### Fourth Modified Example

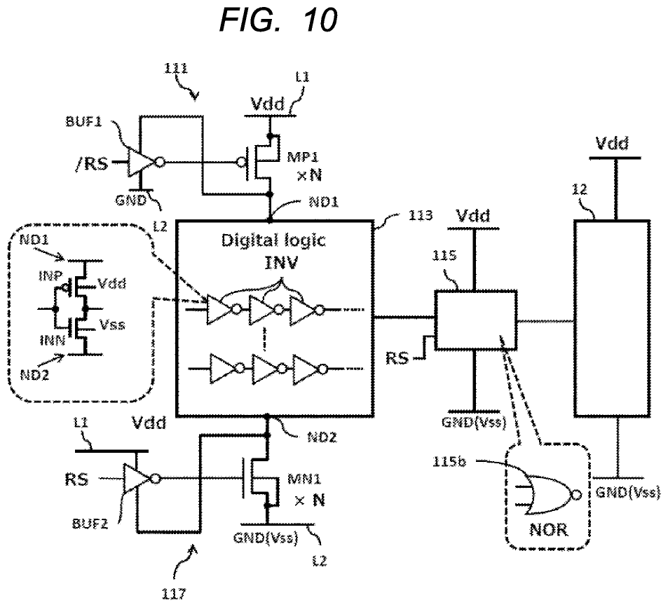

In the fourth modified example, components having the same functions as those in FIG. 2 of the embodiment are denoted by the same reference numerals, and descriptions thereof are omitted. FIG. 10 is a diagram for explaining a configuration example of the logic circuit portion according to a fourth modified example. FIG. 10 differs from FIG. 2 in that the holding circuit 115 is formed of a NOR circuit 115b in FIG. 10. The output of the logic circuit block 113 is connected to one input terminal of the NOR circuit 115b, and the standby signal RS is input to the other input terminal of the NOR circuit 115b.

According to the fourth modified example, since the output signal of the logic circuit block 113 can be fixed to the low level during the standby state, it is possible to suppress the propagation of an indefinite signal and the through current in the circuit block 12. In third modified example, a first modified example or second modified example configuration may be employed.

### Fifth Modified Example

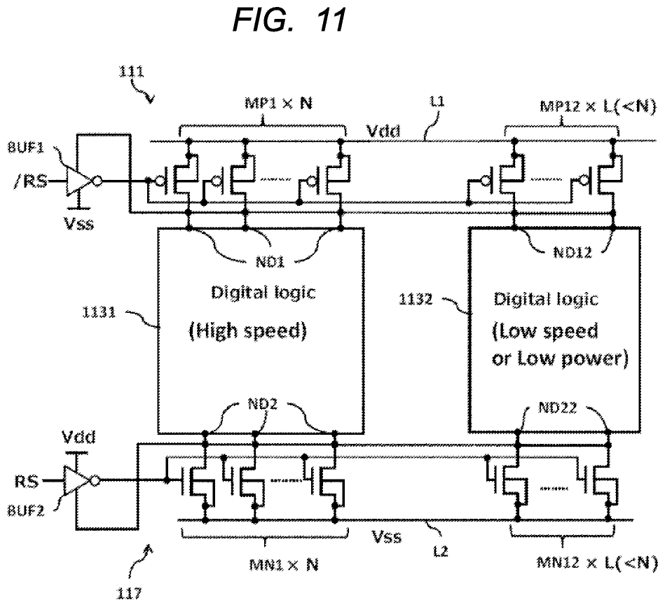

In the fifth modified example, components having the same functions as those in FIG. 2 of the embodiment are denoted by the same reference numerals, and descriptions thereof are omitted. FIG. 11 is a diagram for explaining a configuration example of the logic circuit portion according to a fifth modified example. In FIG. 11, the logic circuit block 113 of FIGS. 1 and 2 includes a logic circuit block (first logic circuit block) 1131 and a logic circuit block (second logic circuit block) 1132. The logic circuit block 1131 is a logic circuit block that performs a high-speed operation, and the logic circuit block 1132 is a logic circuit block that performs a low-speed operation or a logic circuit block that performs an operation with low power consumption. In the switching circuit 111, N P-channel type MOS transistors (first plurality of P-channel type MOS transistors) MP1 are provided for the logic circuit block 1131, and L P-channel type MOS transistors (second plurality of P-channel type MOS transistors) MP12 less than N are provided for the logic circuit block 1132. In the switching circuit 117, N N-channel type MOS transistors (first plurality of N-channel type MOS transistors) MN1 are provided for the logic circuit block 1131, and L (L<N) N-channel type MOS transistors (second plurality of N-channel type MOS transistors) MN12 less than N are provided for the logic circuit block 1132.

Since the high-speed logic circuit block 1131 consumes a large amount of current, the number of P-channel type MOS transistors MP1 and N-channel type MOS transistors MN1 is made larger than the number of P-channel type MOS transistors MP12 and N-channel type MOS transistors MN12 of the logic circuit block 1132.

As a result, in the logic circuit block 1131 operating at high speed, the resistance value between the power supply line L1 and the power supply node ND1 and the resistance value between the ground line L2 and the ground node ND2 can be reduced during the normal operation state. Therefore, since the voltage drop due to these resistance values can be reduced, the logic circuit block 1131 can operate stably. The configuration of the switching circuit 111 is not limited to the configuration of a plurality of N P-channel type MOS transistors MP1 and L P-channel type MOS transistors MP12. For example, a plurality of N P-channel type MOS transistors MP1 may be configured as one 1P channel type MOS transistor, and L P-channel type MOS transistors MP12 may be configured as one 2P channel type MOS transistor. In this instance, a configuration may be adopted in which the size of the gate width (W1) of one 1P channel type MOS transistor is adjusted in accordance with the consumption current of the logic circuit block 1131, and the size of the gate width (W2) of one 2P channel type MOS transistor is adjusted in accordance with the consumption current of the logic circuit block 1132. The gate width (W1) of one 1P channel type MOS transistor is larger than the gate width (W2) of one 2P channel type MOS transistor (W1>W2).

On the other hand, in the logic circuit block 1132, during the normal operation condition, the resistance value between the power supply wiring L1 and the power supply node ND12 and the resistance value between the ground wiring L2 and the ground node ND22 are increased compared with those of the logic circuit block 1131 operating at high speed. However, since the logic circuit block 1132 is a logic circuit block that performs low-speed operation or a logic circuit block that operates with low power consumption, it is not a problem. The configuration of the switching circuit 117 is not limited to the configuration of the plurality of N-channel type MOS transistors MN1 and the plurality of L N-channel type MOS transistors MN12. For example, the N N-channel type MOS transistors MN1 may be configured as one 1N channel type MOS transistor, and the L N-channel type MOS transistors MN12 may be configured as one 2N channel type MOS transistor. In this instance, a configuration may be adopted in which the size of the gate width (W3) of one 1N channel type MOS transistor is adjusted in accordance with the consumption current of the logic circuit block 1131, and the size of the gate width (W3) of one 2N channel type MOS transistor is adjusted in accordance with the consumption current of the logic circuit block 1132. The size of the gate width (W3) of one 1N channel type MOS transistor is larger than the size of the gate width (W4) of one 2N channel type MOS transistor (W3>W4).

Although FIG. 11 shows a configuration example in which two switch circuits 111 and 117 are provided for the logic circuit blocks 1131 and 1132, the present invention is not limited thereto. For example, logic circuit blocks 1131 and 1132 of FIG. 11 may be considered to correspond to logic circuit blocks 113 and 114 of FIG. 5. In this instance, like the logic circuit block 113 shown in FIG. 5, a switch circuit (111) including N P-channel type MOS transistors MP1 and a switch circuit (117) including N N-channel type MOS transistors MN1 can be provided for the logic circuit block 1131. Further, like the logic circuit block 114 and the switch circuits 112 and 118 shown in FIG. 5, a switch circuit (112) including L P-channel type MOS transistors MP12 and a switch circuit (118) including L N-channel type MOS transistors MN12 can be provided for the logic circuit block 1132. According to this, when it is desired to operate the semiconductor device with low power consumption, the logic circuit block 1131 can be made to be in a standby state by the switching circuits 111 and 117, and can be made to operate with low power consumption by using only the logic circuit block 1132.

The fifth modified example can also be applied to the embodiment and first through fourth modified examples.

### Sixth Modified Example

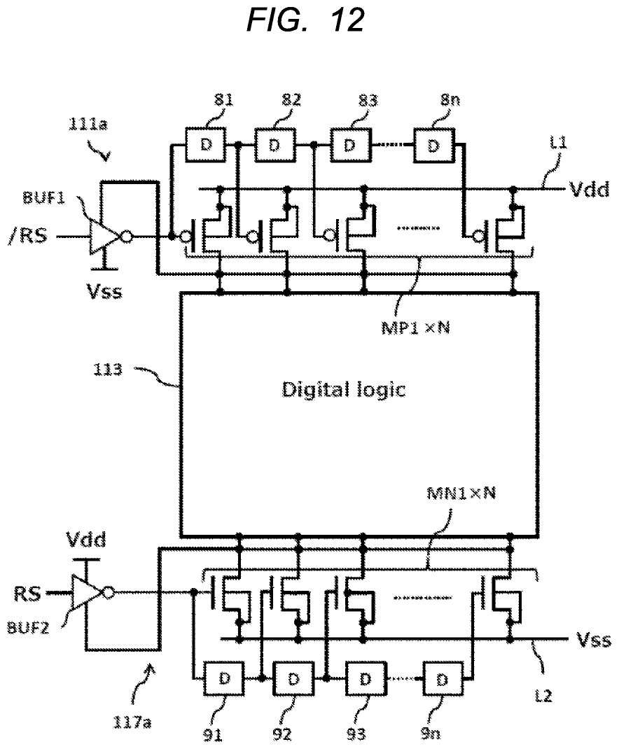

In the sixth modified example, components having the same functions as those in FIG. 2 of the embodiment are denoted by the same reference numerals and descriptions thereof are omitted. FIG. 12 is a diagram for explaining a configuration example of the logic circuit portion according to the sixth modified example. In FIG. 12, switch circuits 111a and 117a are provided in the logic circuit block 113. The switching circuit 111a is provided with a plurality of delay elements (D) 81 to 8n. The switching circuit 117a is provided with a plurality of delay elements (D) 91 to 9n. The plurality of delay elements (D) 81 to 8n and 91 to 9n can be configured by resistive elements, capacitive elements, buffer circuits, and the like.

The plurality of delay elements (D) 81 to 8n are provided for delaying output signals of the buffer circuit BUF1 and transmitting the delayed output signals to the gate electrodes of the N P-channel type MOS transistors MP1. The gate electrode of the first P-channel type MOS transistor MP1 is connected to the output of the buffer circuit BUF1 without passing through the delay element. The gate electrode of the second P-channel type MOS transistor MP1 receives the delayed signal from the delay element 81. The gate electrode of the third P-channel type MOS transistor MP1 receives signals delayed by the two delay elements 81 and 82. The N-th P-channel type MOS transistor MP1 receives signals delayed by the N delay elements 81 to 8n. As a result, the transitions of the N P-channel type MOS transistors MP1 from the OFF-state to the ON-state are not simultaneously shifted, but sequentially shifted in time. The transitions of the N P-channel type MOS transistors MP1 from the ON-state to the OFF-state are not simultaneously transitioned, but are sequentially shifted in time.

The plurality of delay elements (D) 91 to 9n are provided to delay output signals of the buffer circuit BUF2 and transmit the delayed output signals to the gate electrodes of the N channel type MOS transistors MN1. The gate electrode of the first N-channel type MOS transistor MN1 is connected to the output of the buffer circuit BUF2 without passing through the delay element. The gate electrode of the second N-channel type MOS transistor MN1 receives the delayed signal from the delay element 91. The gate electrode of the third N-channel type MOS transistor MN1 receives signals delayed by the two delay elements 91 and 92. The N-th N-channel type MOS transistor MN1 receives signals delayed by the N delay elements 91 to 9n. As a result, the transitions of the N N-channel type MOS transistors MN1 from the OFF-state to the ON-state are not simultaneously shifted, but sequentially shifted in time. The transitions of the N N-channel type MOS transistors MN1 from the ON-state to the OFF-state are not simultaneously transitioned, but are sequentially shifted in time.

In the switching circuits 111 and 117 as shown in FIG. 2, when the N P-channel type MOS transistors MP1 and the N N-channel type MOS transistors MN1 simultaneously transition from the OFF-state to the ON-state, a high-peak-value rush current may occur in the logic circuit portion 113. According to the sixth modified example, the transition of the N P-channel type MOS transistors MP1 from the OFF-state to the ON-state is sequentially shifted in time, and the transition of the N N-channel type MOS transistors MN1 from the OFF-state to the ON-state is sequentially shifted in time, thereby the peaks of the rush current can be reduced.

In the switching circuits 111 and 117 as shown in FIG. 2, when the N P-channel type MOS transistors MP1 and the N N-channel type MOS transistors MN1 simultaneously transition from the ON-state to the OFF-state, the power supply potential Vdd and the grounding potential Vss may fluctuate. According to the sixth modified example, the transition of the N P-channel type MOS transistors MP1 from the ON-state to the OFF-state is sequentially shifted in time, and the transition of the N N-channel type MOS transistors MN1 from the ON-state to the OFF-state is sequentially shifted in time, thereby the potential variation of the power supply potential Vdd or the ground potential Vss can be reduced.

The sixth modified example can also be applied to the embodiment and the first through fifth modified examples.

### Application Example

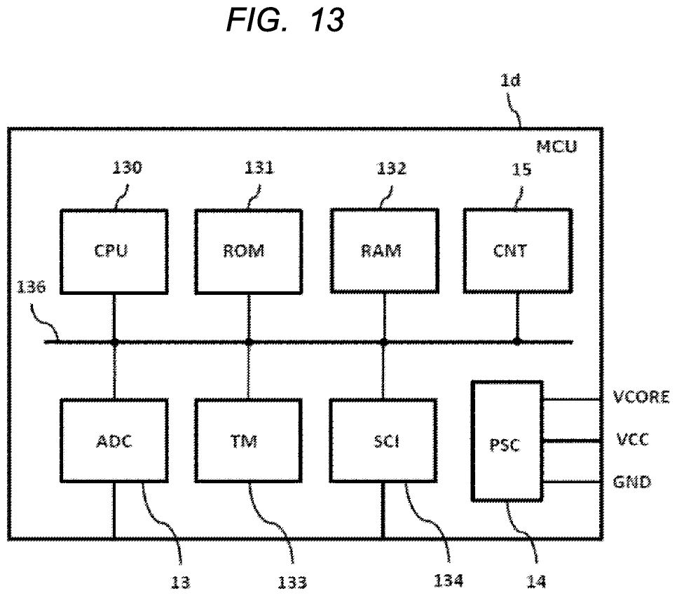

FIG. 13 is a block diagram showing a configuration example of the semiconductor device 1d according to an application example. The semiconductor device 1d are microprocessors MCUs formed on one semiconductor chip. The MCUs include a central processing device (CPU) 130, a nonvolatile memory (ROM) 131, a volatile memory (RAM) 132, a control circuit 15, an analog-to-digital converter circuit (ADC) 13 as an analog circuit, a timer circuit (TM) 133 as a peripheral circuit, a serial communication circuit (SCI) 134, a power supply circuit (PSC) 14, and the like. These circuits 130, 131, 132, 15, 13, 133, and 134 are connected to each other via a bus 136. In this embodiment, the power supply circuit 14 receives the core voltage VCORE, the ground potential GND, and the power supply potential VCC.

The central processing device 130 includes the logic circuit portion 11 shown in FIG. 1. The timer circuit (TM) 133 and the serial communication circuit (SCI) 134 may be viewed as, for example, the circuit portion 12 shown in FIG. 1.

Logic circuits included in the timer circuit (TM) 133 and the serial communication circuit (SCI) 134 may be included in the logic circuit portion 11 shown in FIG. 1.

The configuration of the first through sixth modified examples is applicable to the logic circuit 11 included in the central processing device 130, the timer circuit 133, and the serial communication circuit 134.

While the invention made by the present inventor has been specifically described above based on the Embodiment, the present invention is not limited to the embodiment and the Embodiment described above, and it is needless to say that the present invention can be variously modified.

The plurality of P-channel type MOS transistors MP1 shown in FIGS. 2, 7, 10, and 11 may be formed of one P-channel type MOS transistor. The plurality of N-channel type MOS transistors MN1 shown in FIGS. 2, 9, and 10 may be composed of one P-channel type MOS transistor. The plurality of P-channel type MOS transistors MP12 in FIG. 11 may be formed of one P-channel type MOS transistor. The plurality of N-channel type MOS transistors MN12 in FIG. 11 may be formed of one P-channel type MOS transistor.

Hereinafter, an additional statement will be given of a configuration of another embodiment of the present disclosure.

### APPENDIX 1

A semiconductor device comprising:

a first wiring to which a power supply potential is to be supplied;

a second wiring to which a ground potential is to be supplied;

a first logic circuit block including a first power supply node, a first ground node connected with the second wiring, and a plurality of logic circuits;

a second logic circuit block including a second power supply node, a second ground node connected with the second wiring, and a plurality of logic circuits; and

a switch circuit provided between the first wiring and the first power supply node, and provided between the first wiring and the second power supply node,

wherein the switch circuit includes:

a first P-channel type MOS transistor, a source-drain path of the first P-channel type MOS transistor being coupled between the first wiring and the first power supply node,

a second P-channel type MOS transistor, a source-drain path of the second P-channel type MOS transistor being coupled between the first wiring and the second power supply node,

a third P-channel type MOS transistor, and

a first N-channel type MOS transistor,

wherein a source-drain path of the third P-channel type MOS transistor and a source-drain path of the first N-channel type MOS transistor are coupled in series between the first power supply node and the second wiring, and coupled in series between the second power supply node and the second wiring,

wherein a drain of each of the third P-channel type MOS transistor and the first N-channel type MOS transistor is coupled with a gate electrode of each of the first P-channel type MOS transistor and the second P-channel type MOS transistor,

wherein, during standby state, the third P-channel type MOS transistor is in an ON-state, while the first N-channel type MOS transistor is in an OFF-state,

wherein, during normal operation state, the third P-channel type MOS transistor is in the OFF-state, while the first N-channel type MOS transistor is in the ON-state, and

wherein a width of the first P-channel type MOS transistor is larger than a width of the second P-channel type MOS transistor.

### APPENDIX 2

The semiconductor device according to APPENDIX 1, wherein the first logic circuit block conducts a high-speed operation than the second logic circuit block.

### APPENDIX 3

A semiconductor device comprising:

a first wiring to which a power supply potential is to be supplied;

a second wiring to which a ground potential is to be supplied;

a first logic circuit block including a first power supply node connected with the first wiring, a first ground node, and a plurality of logic circuits;

a second logic circuit block including a second power supply node connected with the first wiring, a second ground node, and a plurality of logic circuits; and

a switch circuit provided between the first ground node and the second wiring, and provided between the second ground node and the second wiring,

wherein the switch circuit includes:

a first N-channel type MOS transistor, a source-drain path of the first N-channel type MOS transistor being coupled between the first ground node and the second wiring,

a second N-channel type MOS transistor, a source-drain path of the second N-channel type MOS transistor being coupled between the second ground node and the second wiring,

a third N-channel type MOS transistor, and

a first P-channel type MOS transistor,

wherein a source-drain path of the first P-channel type MOS transistor and a source-drain path of the third N-channel type MOS transistor are coupled in series between the first ground node and the second wiring, and coupled in series between the second ground node and the second wiring,

wherein a drain of each of the first P-channel type MOS transistor and the third N-channel type MOS transistor is coupled with a gate electrode of each of the first N-channel type MOS transistor and the second N-channel type MOS transistor,

wherein, during standby state, the first P-channel type MOS transistor is in an OFF-state, while the third N-channel type MOS transistor is in an ON-state,

wherein, during normal operation state, the first P-channel type MOS transistor is in the ON-state, while the third N-channel type MOS transistor is in the OFF-state, and wherein a width of the first P-channel type MOS transistor is larger than a width of the second P-channel type MOS transistor.

### APPENDIX 4

The semiconductor device according to APPENDIX 3,

wherein the first logic circuit block conducts a high-speed operation than the second logic circuit block.

What is claimed is:

1. A semiconductor device comprising:
a first wiring to which a power supply potential is to be supplied;
a second wiring to which a ground potential is to be supplied;
a logic circuit block including a power supply node, a ground node, and a plurality of logic circuits;
a first switch circuit provided between the first wiring and the power supply node; and
a second switch circuit provided between the ground node and the second wiring,
wherein the first switch circuit includes a plurality of P-channel type MOS transistors, a source-drain path of each of the plurality of P-channel type MOS transistors being coupled between the first wiring and the power supply node,
wherein the second switch circuit includes a plurality of N-channel type MOS transistors, a source-drain path of each of the plurality of N-channel type MOS transistors being coupled between the ground node and the second wiring,
wherein, during standby state, the plurality of P-channel type MOS transistors is diode-connected, and
wherein, during standby state, the plurality of N-channel type MOS transistors is diode-connected.

2. The semiconductor device according to claim 1,
wherein the first switch circuit includes a first P-channel type MOS transistor and a first N-channel type MOS transistor,
wherein a source-drain path of the first P-channel type MOS transistor and a source-drain path of the first N-channel type MOS transistor are coupled in series between the power supply node and the second wiring,
wherein a drain of each of the first P-channel type MOS transistor and the first N-channel type MOS transistor is coupled with a gate electrode of each of the plurality of P-channel type MOS transistors,
wherein the second switch circuit includes a second P-channel type MOS transistor and a second N-channel type MOS transistor,
wherein a source-drain path of the second P-channel type MOS transistor and a source-drain path of the second N-channel type MOS transistor are coupled in series between the first wiring and the ground node,
wherein a drain of each of the second P-channel type MOS transistor and the second N-channel type MOS transistor is coupled with a gate electrode of each of the plurality of N-channel type MOS transistors, and
wherein, during standby state, the first P-channel type MOS transistor and the second N-channel type MOS transistor are in an ON-state, while the first N-channel type MOS transistor and the second P-channel type MOS transistor are in an OFF-state.

3. The semiconductor device according to claim 2,
wherein, during normal operation state, the first P-channel type MOS transistor and the second N-channel type MOS transistor are in the OFF-state, while the first N-channel type MOS transistor and the second P-channel type MOS transistor are in the ON-state.

4. The semiconductor device according to claim 3, further comprising:
a circuit portion; and
a holding circuit arranged between an output of the logic circuit block and an input of the circuit portion,
wherein the holding circuit includes a holding function retaining the output of the logic circuit block.

5. The semiconductor device according to claim 4,
wherein the holding circuit includes one of a D-latch circuit and a NOR circuit.

6. The semiconductor device according to claim 1,
wherein each of the plurality of logic circuits includes:
a P-channel type MOS transistor formed in N-type well, and
a N-channel type MOS transistor formed in P-type well,
wherein the power supply potential is to be supplied to the N-type well, and
wherein the ground potential is to be supplied to the P-type well.

7. A semiconductor device comprising:
a first wiring to which a power supply potential is to be supplied;
a second wiring to which a ground potential is to be supplied;
a logic circuit block including a power supply node connected with the first wiring, a ground node, and a plurality of logic circuits; and
a switch circuit provided between the ground node and the second wiring,
wherein the switch circuit includes a plurality of N-channel type MOS transistors, a source-drain path of each of the plurality of N-channel type MOS transistors being coupled between the ground node and the second wiring, and
wherein, during standby state, the plurality of N-channel type MOS transistors is diode-connected.

8. The semiconductor device according to claim 7,
wherein the switch circuit includes a P-channel type MOS transistor and a N-channel type MOS transistor,
wherein a source-drain path of the P-channel type MOS transistor and a source-drain path of the N-channel type MOS transistor are coupled in series between the first wiring and the ground node,
wherein a drain of each of the P-channel type MOS transistor and the N-channel type MOS transistor is coupled with a gate electrode of each of the plurality of N-channel type MOS transistors,
wherein, during standby state, the N-channel type MOS transistor is in an ON-state, while the P-channel type MOS transistor is in an OFF-state, and
wherein, during normal operation state, the N-channel type MOS transistor is in the OFF-state, while the P-channel type MOS transistor is in the ON-state.

9. The semiconductor device according to claim 8,
wherein the logic circuit block includes a first logic circuit block and a second logic circuit block,
wherein the plurality of N-channel type MOS transistors of the switch circuit include:
a plurality of first N-channel type MOS transistors provided for the first logic circuit block, and
a plurality of second N-channel type MOS transistors provided for the second logic circuit block, and
wherein the number of the plurality of first N-channel type MOS transistors is larger than the number of the plurality of second N-channel type MOS transistors.

10. The semiconductor device according to claim 9,
wherein the first logic circuit block conducts a high-speed operation than the second logic circuit block.

11. The semiconductor device according to claim 7,
wherein the switch circuit includes delay elements,
wherein the delay elements are coupled between gate electrodes of the plurality of N-channel type MOS transistors, respectively, such that one of the delay elements is coupled between the two N-channel type MOS transistors which are corresponding to the one.

12. The semiconductor device according to claim 7,
wherein each of the plurality of logic circuits includes:
a P-channel type MOS transistor formed in N-type well, and
a N-channel type MOS transistor formed in P-type well,
wherein the power supply potential is to be supplied to the N-type well, and
wherein the ground potential is to be supplied to the P-type well.

13. A semiconductor device comprising:
a first wiring to which a power supply potential is to be supplied;
a second wiring to which a ground potential is to be supplied;
a logic circuit block including a power supply node, a ground node connected with the second wiring, and a plurality of logic circuits; and
a switch circuit provided between the first wiring and the power supply node,
wherein the switch circuit includes a plurality of P-channel type MOS transistors, a source-drain path of each of the plurality of P-channel type MOS transistors being coupled between the first wiring and the power supply node, and
wherein, during standby state, the plurality of P-channel type MOS transistors is diode-connected.

14. The semiconductor device according to claim 13,
wherein the switch circuit includes a P-channel type MOS transistor and a N-channel type MOS transistor,
wherein a source-drain path of the P-channel type MOS transistor and a source-drain path of the N-channel type MOS transistor are coupled in series between the power supply node and the second wiring,
wherein a drain of each of the P-channel type MOS transistor and the N-channel type MOS transistor is coupled with a gate electrode of each of the plurality of P-channel type MOS transistors,
wherein, during standby state, the P-channel type MOS transistor is in an ON-state, while the N-channel type MOS transistor is in an OFF-state, and
wherein, during normal operation state, the P-channel type MOS transistor is in the OFF-state, while the N-channel type MOS transistor is in the ON-state.

15. The semiconductor device according to claim 14,
wherein the logic circuit block includes a first logic circuit block and a second logic circuit block,
wherein the plurality of P-channel type MOS transistors of the switch circuit include:
a plurality of first P-channel type MOS transistors provided for the first logic circuit block, and
a plurality of second P-channel type MOS transistors provided for the second logic circuit block, and
wherein the number of the plurality of first P-channel type MOS transistors is larger than the number of the plurality of second P-channel type MOS transistors.

16. The semiconductor device according to claim 15,
wherein the first logic circuit block conducts a high-speed operation than the second logic circuit block.

17. The semiconductor device according to claim 13,
wherein the switch circuit includes delay elements,
wherein the delay elements are coupled between gate electrodes of the plurality of P-channel type MOS transistors, respectively, such that one of the delay elements is coupled between the two P-channel type MOS transistors which are corresponding to the one.

18. The semiconductor device according to claim 13,
wherein each of the plurality of logic circuits includes:
a P-channel type MOS transistor formed in N-type well, and
a N-channel type MOS transistor formed in P-type well,
wherein the power supply potential is to be supplied to the N-type well, and
wherein the ground potential is to be supplied to the P-type well.
